(19) United States
(12) Patent Application Publication
(10) Pub. No.: US 2003/0090326 A1
(43) Pub. Date: May 15, 2003

(54) Transimpedance amplifier with dual gain outputs

(76) Inventors: Victor Pogrebinsky, San Jose, CA (US); Vladimir Pogrebinsky, Campbell, CA (US)

Correspondence Address: Michael J. Halbert, SKJERVEN MORRILL MacPHERSON LLP, Suite 700, 25 Metro Drive, San Jose, CA, 95110-1349, US

(21) Appl. No.: 10/003,359

(22) Filed: Nov. 14, 2001

(51) Int. Cl. H03F 3/08

(52) U.S. Cl. 330/308

(57) ABSTRACT

A transimpedance amplifier system includes a current source, such as a photodiode, coupled between two transimpedance amplifiers, each having feedback circuits with different impedances. Thus, for example, the cathode of a photodiode is coupled to a first transimpedance amplifier while the anode of the photodiode is coupled to the second transimpedance amplifier. Consequently, two voltage gains can be achieved without the use of conventional switched feedback circuits or the use of additional gain stages. A clamp circuit in parallel with one of the feedback circuits can be used to ensure that the both transimpedance amplifiers operate within their linear regions.

### FIELD OF THE INVENTION

The present invention relates to transimpedance amplifiers and in particular to transimpedance amplifiers with more than one voltage gain output.

### BACKGROUND

Transimpedance amplifiers are known in the art. FIG. 1 shows a schematic view of a conventional transimpedance amplifier 10. As shown in FIG. 1, transimpedance amplifier 10 includes an operational amplifier (“op-amp”) 12 with the noninverting input coupled to ground and the inverting input coupled to the cathode of photodiode 14. The anode of photodiode 14 is coupled to ground. The photodiode 14 operates as a current source with high output impedance. A feedback circuit 16 is coupled between the output terminal and the inverting input terminal of the op-amp 12.

The voltage gain of transimpedance amplifier 10 is determined by the feedback circuit 16. To achieve more than a single gain in a transimpedance amplifier, the feedback circuit can be switched or additional voltage gain stages may be added. A switching feedback circuit may include multiple resistors of different values that can be switchably coupled between the output terminal and the inverting input terminal of the op-amp 12. Thus, for example, as shown in FIG. 1, the feedback circuit 16 may include a number of resistors 18 and 20, a capacitor 19, and a transistor 22 in parallel with one of the resistors. Thus, by turning on and off the transistor, the impedance of the feedback circuit 16 may be altered. However, placing switching components in series with the feedback circuit affects the accuracy, stability, noise and frequency of the response.

Alternatively, a separate gain stage 24, including another op-amp 26 and feedback circuit 28 may be added to the output of transimpedance amplifier 10 through a resistor 30. However, adding a voltage gain stage to the output terminal of transimpedance amplifier 10 will unfortunately multiply noise and offset.

Thus, what is needed is a transimpedance amplifier system that provides more than one voltage gain output but that does not suffer from loss of accuracy, stability, or increased noise and offset as found in conventional systems.

### SUMMARY

A transimpedance amplifier system, in accordance with the present invention, provides two voltage output signals with different gains without loss of accuracy, stability or increasing noise or offset. The transimpedance amplifier system includes two transimpedance amplifiers with a current source, such as a photodiode, coupled between the inverting input terminals of the two transimpedance amplifiers.

In accordance with one embodiment of the present invention, the transimpedance amplifier system includes a current source that provides a current signal from a first terminal and a second terminal, a first transimpedance amplifier that receives the current signal from the first terminal and converts the current signal to a first voltage output signal with a first gain; and a second transimpedance amplifier that receives the current signal from a second terminal and converts the current signal to a second voltage output signal with a second gain. The current source may be, e.g., a photodiode. In one embodiment a clamp circuit is provided in parallel with one of the feedback circuits of the transimpedance amplifiers. The clamp circuit holds the transimpedance amplifiers within their linear operating regions inside the full scale range of the circuit.

In another embodiment of the present invention, a method of converting a current signal to a dual voltage signals with different gains includes providing a current signal from a current source, such as a photodiode. The current signal from a first terminal of the current source is received and transformed to produce a first output voltage signal having a first gain. The current signal from a second terminal of the current source is also received and transformed to produce a second output voltage signal having a second gain. Transforming the current signal to produce a voltage signal includes converting the voltage output signal to a feedback current signal, combining the feedback current signal with the current signal from the current source, and converting the combined current signals into the voltage output signal, for example as performed by a transimpedance amplifier.

### BRIEF DESCRIPTION OF THE DRAWINGS

FIG. 1 shows a schematic view of a conventional transimpedance amplifier having multiple voltage gain outputs.

FIG. 2 is a schematic view of a transimpedance amplifier system having dual voltage gain outputs in accordance with an embodiment of the present invention.

FIG. 3 is a schematic diagram of one embodiment of a clamp circuit that may be used with the transimpedance amplifier system shown in FIG. 2.

### DETAILED DESCRIPTION

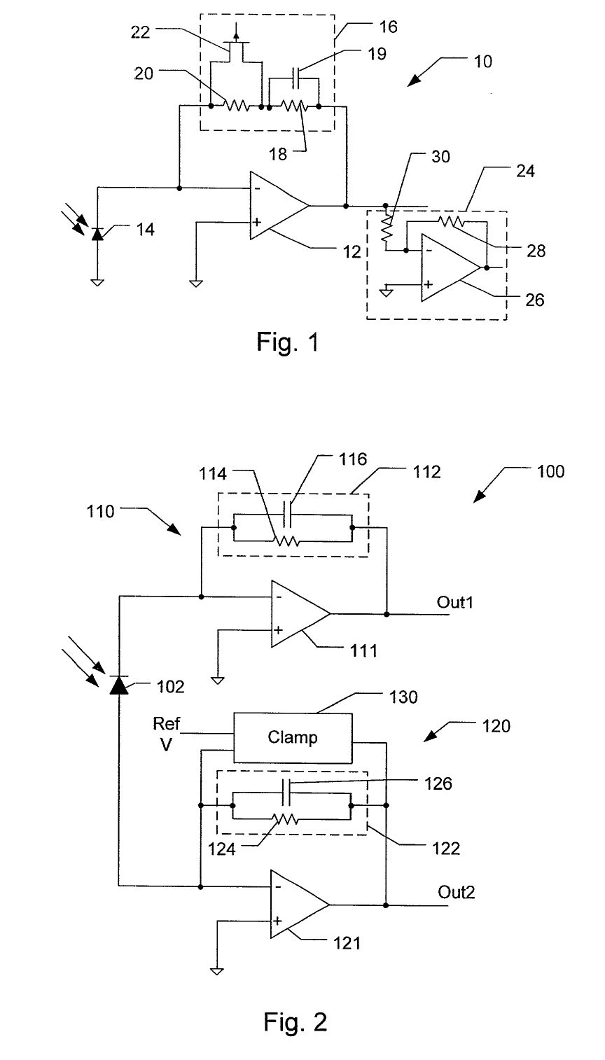

FIG. 2 is a schematic view of a transimpedance amplifier system 100 having dual voltage gain outputs in accordance with an embodiment of the present invention. Advantageously, transimpedance amplifier system 100 uses two separate transimpedance amplifiers (which may be within the same package) and feedback circuits to produce the different voltage gains and, thus, eliminates problems with loss of accuracy, stability, or increased noise and offset found in conventional systems. The dual voltage gain transimpedance amplifier system 100 maybe particularly useful in light power measurements, which is in general well known to those skilled in the art.

As shown in FIG. 2, transimpedance amplifier system 100 includes a current source, such as a photodiode 102, between a first transimpedance amplifier 110 with a feedback circuit 112 that provides a first gain and a second transimpedance amplifier 120 with a feedback circuit, 122 that provides a second (different) gain. As shown in FIG. 2, a photodiode 102 may be used with the cathode coupled to the first transimpedance amplifier 110 and the anode coupled to the second transimpedance amplifier 120. The application of a photodiode 102 may be utilized, e.g., for light power measurements. A photodiode, such as a part number FD1500W manufactured by Fermionics, Inc. in Simi Valley, Calif., may be used.

Transimpedance amplifiers 110 and 120 each include op-amps 111 and 121, respectively with their noninverting input terminals coupled a low impedance voltage source. For example, as shown in FIG. 2, the noninverting input terminals are coupled to ground. The inverting input terminal of op-amp 111 is coupled to the cathode of photodiode 102, while the inverting input terminal of op-amp 121 is coupled to the anode of photodiode 102. While FIG. 2 shows transimpedance amplifier system 100 using two separate op-amps, it should be understood that the op-amps may be within the same package, e.g., as a dual amplifier such as that manufactured by Texas Instruments, as part number OPA2132U.

The feedback circuit 112 includes, e.g., a resistor 114 and a capacitor 116 in parallel between the output Out1 of op-amp 111 and the inverting input terminal of op-amp 111. Similarly, the feedback circuit 122 includes, e.g., a resistor 124 and a capacitor 126 in parallel between the output Out2 of op-amp 121 and the inverting input terminal of op-amp 121.

The specific values of the components in feedback circuits 112 and 122 are chosen for the desired response, i.e., gain and frequency, for the device. By way of example, in feedback circuit 112, resistor 114 may have a resistance of 50 KΩ and capacitor 116 has a capacitance of 220 pF, while in feedback circuit 122, resistor 124 may have a resistance of 500 KΩ and capacitor 126 has a capacitance of 33 pF Of course, any appropriate RC values may be used to achieve the desired gain and frequency. It should be understood that feedback circuits 112 and 122 are exemplary and that other feedback circuits may be used to achieve a desired transimpedance gain.

In operation, the current signal from the cathode of photodiode 102 is received by transimpedance amplifier 110, while the current signal from the anode of photodiode 102 is received by transimpedance amplifier 120. The transimpedance amplifiers 110 and 120 transform the received current signal to produce the voltage output signal at the output terminals Out1 and Out2, respectively. The voltage output signals are received by feedback circuits 112 and 122, which convert the output voltage signals to feedback current signals. The feedback current signals are combined with the current signal from the photodiode 102, i.e,. the feedback loop is closed, and the combined feedback current signal and current signals from the photodiode 102 are transformed to the voltage output signals by op-amps 111 and 121.

The voltage V_{Out1} at the output of the output terminal Out1 of transimpedance amplifier 110 is V_{Out1}=I×Z₁₁₂, where I is the current through the current source, i.e., photodiode 102, and Z₁₁₂ is the impedance of the feedback circuit 112. Similarly, the voltage V_{Out2} at the output of the output terminal Out2 of transimpedance amplifier 120 is V_{Out}₂=−(I×Z₁₂₂), where again I is the current through the current source, i.e., photodiode 102, and Z₁₂₂ is the impedance of the feedback circuit 112. In the case where the impedance of feedback circuit 122 is greater than the impedance of feedback circuit 112, i.e., Z₁₂₂>Z₁₁₂, the op-amp 121 will reach saturation earlier than op-amp 111. Consequently, the linear mode of operation for the transimpedance amplifier system 100 will be disturbed when the following equation is not valid:

$$\frac{{V}_{Out1}}{{Z}_{112}} = - \frac{{V}_{Out2}}{{Z}_{122}} \qquad \text{eq. 1}$$

To avoid the disturbance of the linear mode of operation, a clamp circuit 130 is coupled in parallel with the feedback circuit 122, i.e., between the output Out2 of op-amp 121 and the inverting input terminal of op-amp 121. The clamp circuit 130 receives a reference voltage (Ref V), which sets the clamping level. The clamping level is chosen to be in the linear range of operation of the op-amp 121.

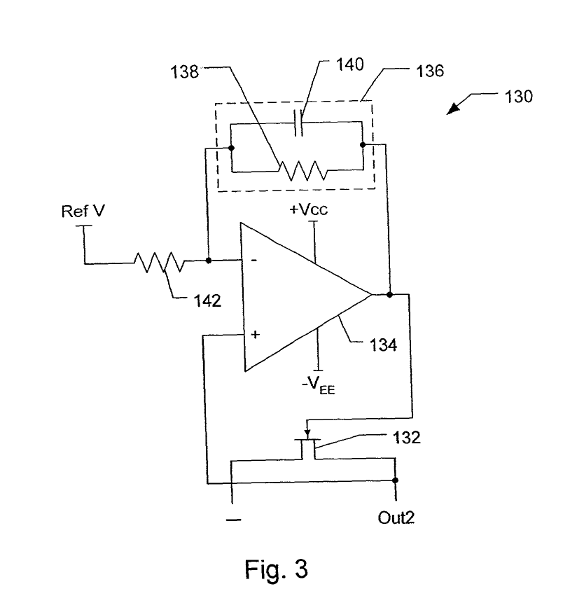

FIG. 3 is a schematic diagram of one embodiment of clamp circuit 130. Clamp circuit 130 includes a clamping element 132, e.g., an n-channel JFET transistor, such part number SST4119 manufactured by Vishay Siliconix, located in Malvern, Pa., coupled between the output terminal Out2 of op-amp 121 (shown in FIG. 2) and the inverting input terminal of the op-amp 121, shown in FIG. 3 as “−”. The control terminal of clamping element 132 is coupled to a control circuit. Thus, for example, the control circuit may be an op-amp 134, such as that manufactured by Texas Instruments as part number OPA2227, which has the output terminal connected to the gate of the clamping element 132. The noninverting input terminal of op-amp 134 is connected to the output terminal Out2 of op-amp 121 and the inverting input terminal of op-amp 134 is connected to the output terminal through a feedback circuit 136, including, e.g., a resistor 138 and capacitor 140. The inverting input of op-amp 134 is also connected to a reference voltage (Ref V) through a resistor 142. Op-amp 134 receives +Vcc and −V_{EE}, which may be, e.g., +15V and −15V, while the reference voltage (Ref V) is, e.g,. 10.5V. In feedback circuit 136, the resistor 138 may have a resistance, e.g., of 500 KΩ and the capacitor may have a capacitance of 100 pF, while the resistor 142 may have a resistance of 5KΩ. Of course, these values may vary depending on the desired operation of the clamp circuit 130.

Although the invention has been described with reference to particular embodiments and particular components, the description is only an example of the invention's application and should not be taken as a limitation. Various adaptations and combinations of features of the embodiments disclosed are within the scope of the invention as defined by the following claims.

What is claimed is:

1. A transimpedance amplifier system, comprising:
a current source providing a current signal from a first terminal and a second terminal;
a first transimpedance amplifier receiving the current signal from the first terminal and converting the current signal to a first voltage output signal with a first gain; and
a second transimpedance amplifier receiving the current signal from a second terminal and converting the current signal to a second voltage output signal with a second gain.

2. The transimpedance amplifier system of claim 1, wherein the current source is a photodiode having a cathode and an anode, the first transimpedance amplifier receiving the current signal from the cathode and the second transimpedance amplifier receiving the current signal from the anode.

3. The transimpedance amplifier system of claim 1, wherein:
the first transimpedance amplifier comprises a first operational amplifier having a noninverting terminal coupled to a voltage supply, the inverting terminal, an output terminal, and a feedback circuit coupled between the inverting terminal and the output terminal, the feedback circuit having a first impedance; and
the second transimpedance amplifier comprises a second operational amplifier having a noninverting terminal coupled to the voltage supply, the inverting terminal, an output terminal, and a feedback circuit coupled between the inverting terminal and the output terminal, the feedback circuit having a second impedance that is different than the first impedance.

4. The transimpedance amplifier system of claim 3, wherein the voltage supply is ground.

5. The transimpedance amplifier system of claim 1, further comprising a clamp circuit coupled to the second transimpedance amplifier for holding the second transimpedance amplifier within its linear operating range.

6. The transimpedance amplifier system of claim 3, further comprising a clamp circuit for holding the second transimpedance amplifier within its linear operating range, the clamp circuit comprising:
a clamping element coupled between the output terminal and the inverting terminal of the second transimpedance amplifier, the clamping element having a control terminal coupled to a control circuit.

7. The transimpedance amplifier system of claim 6, wherein the control circuit comprises a reference voltage source, an operational amplifier having an inverting terminal coupled to the reference voltage source, a noninverting terminal coupled to the output terminal of the second transimpedance amplifier, an output terminal coupled to the control terminal of the clamping element, and a feedback circuit coupled between the inverting terminal and the output terminal.

8. A transimpedance amplifier system, comprising:
a first transimpedance amplifier having an inverting terminal, an output terminal, and a feedback circuit with a first impedance coupled between the output terminal and the inverting terminal;
a second transimpedance amplifier having an inverting terminal, an output terminal, and a feedback circuit with a second impedance coupled between the output terminal and the inverting terminal, the second impedance being different then the first impedance; and
a current source coupled between the inverting terminal of the first transimpedance amplifier and the inverting terminal of the second transimpedance amplifier.

9. The transimpedance amplifier system of claim 8, wherein the current source is a photodiode having a cathode coupled to the inverting terminal of the first transimpedance amplifier and a anode coupled to the inverting terminal of the second transimpedance amplifier.

10. The transimpedance amplifier system of claim 8, wherein:
the first transimpedance amplifier comprises a first operational amplifier having a noninverting terminal coupled to a voltage supply, the inverting terminal, an output terminal, and a feedback circuit coupled between the inverting terminal and the output terminal, the feedback circuit having a first impedance; and
the second transimpedance amplifier comprises a second operational amplifier having a noninverting terminal coupled to the voltage supply, the inverting terminal, an output terminal, and a feedback circuit coupled between the inverting terminal and the output terminal, the feedback circuit having a second impedance that is different than the first impedance.

11. The transimpedance amplifier system of claim 10, wherein the voltage supply is ground.

12. The transimpedance amplifier system of claim 8, further comprising a clamp circuit coupled between the output terminal and the inverting terminal of the second transimpedance amplifier.

13. The transimpedance amplifier system of claim 12, wherein the clamp circuit comprises:
a clamping element coupled between the output terminal and the inverting terminal of the second transimpedance amplifier, the clamping element having a control terminal;
a reference voltage source;
an operational amplifier having an inverting terminal coupled to the reference voltage source, a noninverting terminal coupled to the output terminal of the second transimpedance amplifier, an output terminal coupled to the control terminal of the clamping element; and
a feedback circuit coupled between the inverting terminal and the output terminal.

14. A method of converting a current signal to dual voltage signals with different gains, the method comprising:
providing a current signal from two terminals of a current source;
receiving the current signal from a first terminal of the current source;
transforming the current signal from the first terminal to produce a first output voltage signal having a first gain;
receiving the current signal from a second terminal of the current source; and
transforming the current signal from the second terminal to produce a second output voltage signal having a second gain.

15. The method of claim 14, wherein transforming the current signal from the first terminal to produce a first output voltage signal having a first gain comprises:
converting the first voltage output signal to a first feedback current signal;
combining the first feedback current signal and the current signal and converting the combined first feedback current signal and current signal into the first voltage output signal; and
wherein transforming the current signal from the second terminal to produce a second output voltage signal having a second gain comprises:
converting the second voltage output signal to a second feedback current signal;
combining the second feedback current signal and the current signal and converting the combined second feedback current signal and current signal into the second voltage output signal.

16. The method of claim 14, wherein providing a current signal comprises producing a current signal from the anode and cathode of a photodiode.

17. The method of claim 14, further comprising clamping the second output voltage level at a predetermined voltage level.
